(19) United States
(12) Patent Application Publication
(10) Pub. No.: US 2019/0250205 A1
(43) Pub. Date: Aug. 15, 2019

(54) THERMAL MODEL BASED HEALTH ASSESSMENT OF IGBT

(71) Applicant: GM GLOBAL TECHNOLOGY OPERATIONS LLC, Detroit, MI (US)

(72) Inventors: Azeem Sarwar, Rochester Hills, MI (US); Madi Zholbaryssov, Champaign, IL (US); Wesley G. Zanardelli, Rochester, MI (US); Yo Chan Son, Rochester Hills, MI (US)

(21) Appl. No.: 15/895,425

(22) Filed: Feb. 13, 2018

(51) Int. Cl. G01R 31/26; G06F 17/50; G08B 21/18

(52) U.S. Cl. CPC G01R 31/2619; H02P 27/06; G08B 21/182; G06F 17/5036

(57) ABSTRACT

An apparatus and method for determining occurrence of a fault at an insulated-gate bipolar transistor (IGBT) module is disclosed. The IGBT module and apparatus can be part of an electric vehicle. A sensor obtains a measurement of a thermal parameter of the IGBT module. A processor receives the measured thermal parameter from the sensor, and runs a model of the IGBT module to determine a thermal parameter of the IGBT module under normal operation conditions. The processor provides an alert signal to indicate the occurrence of the fault when a difference between the estimated thermal parameter and the measured thermal parameter is greater than or equal to a selected threshold.

### INTRODUCTION

The subject disclosure relates to a system and method for vehicle testing and maintenance and, in particular, to a method of determining a health or condition of an insulated gate bipolar transistor (IGBT) junction used in operation of the vehicle.

Electrical vehicles use insulated gate bipolar transistor (IGBT) junctions in order to convert direct current (DC) power from a battery into alternating current (AC) power that goes into the electric motor and drives the wheels though a transmission module. IGBT junctions degrade due to thermo-mechanical stress caused by electrical and environmental loading, which causes gradual deterioration of materials. If left undetected, minor faults and fissures can grow to cause a failure of the IGBT junction. Accordingly, it is desirable to provide a method for identifying a health or condition of an IGBT junction in order to maintain operation of the vehicle.

### SUMMARY

In one exemplary embodiment, a method of determining occurrence of a fault at an insulated-gate bipolar transistor (IGBT) module is disclosed. The method includes operating a model of the IGBT module on a processor to estimate a thermal parameter of the IGBT module under normal operation conditions, measuring a thermal parameter of the IGBT module via a sensor, and providing an alert signal to indicate the occurrence of the fault when a difference between the estimated thermal parameter and the measured thermal parameter is greater than a selected threshold.

In addition to one or more of the features described herein, the thermal parameter is at least one of a thermal resistance between the IGBT junction and a heat sink, a thermal resistance between a diode and the IGBT junction, a thermal resistance of a heat sink, and a thermal resistance of a thermistor. The thermal parameter is one of a thermal capacitance, a thermal resistance, and a thermal time constant of an element of the IGBT module. The estimated thermal parameters obtained from the model of the IGBT module are used to determine the selected threshold.

In addition to one or more of the features described herein, the method includes determining a remaining useful life of the IGBT module. Determining the remaining useful life includes obtaining an effective number of power cycles related to a summation of power cycles at a plurality of average temperatures and temperature swings. An estimation technique is applied to the model of the IGBT module to estimate the average temperature and temperature swing of the power cycles.

In another exemplary embodiment, an apparatus for assessing a condition of an insulated-gate bipolar transistor (IGBT) module is disclosed. The apparatus includes a sensor configured to obtain a measurement of a thermal parameter of the IGBT module, and a processor. The processor is configured to receive the measured thermal parameter from the sensor, run a model of the IGBT module to determine a thermal parameter of the IGBT module under normal operation conditions, and provide an alert signal to indicate the occurrence of the fault when a difference between the estimated thermal parameter and the measured thermal parameter is greater than or equal to a selected threshold.

In addition to one or more of the features described herein, the thermal parameter is at least one of a thermal resistance between the IGBT junction and a heat sink, a thermal resistance between a diode and the IGBT junction, a thermal resistance of a heat sink, and a thermal resistance of a thermistor. The thermal parameter is one of a thermal capacitance, a thermal resistance, and a thermal time constant of an element of the IGBT module. The processor determines the selected threshold from the estimated thermal parameters obtained by running the model of the IGBT module.

In addition to one or more of the features described herein, the processor is further configured to determine a remaining useful life of the IGBT junction. The remaining useful life includes an effective number of power cycles related to a summation of power cycles at a plurality of average temperatures and temperature swings. The processor is further configured to apply an estimation technique to the model of the IGBT module to estimate the average temperature and temperature swing of the power cycles.

In yet another exemplary embodiment, a vehicle is disclosed. The vehicle includes an IGBT module, a sensor configured to obtain a measurement of a thermal parameter of the IGBT module, and a processor. The processor is configured to receive the measured thermal parameter from the sensor, run a model of the IGBT module to determine a thermal parameter of the IGBT module under normal operation conditions, and provide an alert signal to indicate the occurrence of the fault when a difference between the estimated thermal parameter and the measured thermal parameter is greater than or equal to a selected threshold.

In addition to one or more of the features described herein, the thermal parameter is at least one of a thermal resistance between the IGBT junction and a heat sink, a thermal resistance between a diode and the IGBT junction, a thermal resistance of a heat sink, and a thermal resistance of a thermistor. The thermal parameter is one of a thermal capacitance, a thermal resistance, and a thermal time constant of an element of the IGBT module. The processor is further configured to determine the selected threshold from the estimated thermal parameters obtained by running the model of the IGBT module.

In addition to one or more of the features described herein, the processor is further configured to determine a remaining useful life of the IGBT junction from an effective number of power cycles related to a summation of power cycles at a plurality of average temperatures and temperature swings. The processor is further configured to apply an estimation technique to the model of the IGBT module to estimate the average temperature and temperature swing of the power cycles.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 shows a schematic diagram of an electrical system of a vehicle, such as an electrical vehicle;

FIG. 2 shows an illustrative thermal model of the IGBT module that models a thermal response of various elements of the IGBT module;

FIG. 3 shows a flowchart illustrating a method for running the model for the IGBT module shown in FIG. 2;

FIG. 4 shows two graphs showing illustrative heating curves for the IGBT junction;

FIG. 5 shows a flowchart illustrating a method of determining a faulty condition of the IGBT module using the model of FIG. 2;

FIG. 6A shows a plot of thermal resistance between the IGBT junction and the heat sink;

FIG. 6B shows a temporal plot of junction temperature that is related to the plot of thermal resistance shown in FIG. 6A;

FIG. 6C shows a plot of thermal resistance for the heat sink;

FIG. 6D shows a temporal plot of junction temperature that is related to the plot of thermal resistance for the heat sink as shown in FIG. 6C;

FIG. 7 shows a graph illustrating active power cycling;

FIG. 8 shows a graph illustrating a set of power cycling capability curves;

FIG. 9 shows a flowchart illustrating a method of determining remaining useful life of the IGBT module;

FIG. 10 shows simulation results demonstrating how the method disclosed herein predicts the RUL of an IGBT module; and

FIG. 11 shows a flowchart illustrating a method of providing a warning or alert based on a remaining useful life of an IGBT junction.

### DETAILED DESCRIPTION

The following description is merely exemplary in nature and is not intended to limit the present disclosure, its application or uses. It should be understood that throughout the drawings, corresponding reference numerals indicate like or corresponding parts and features.

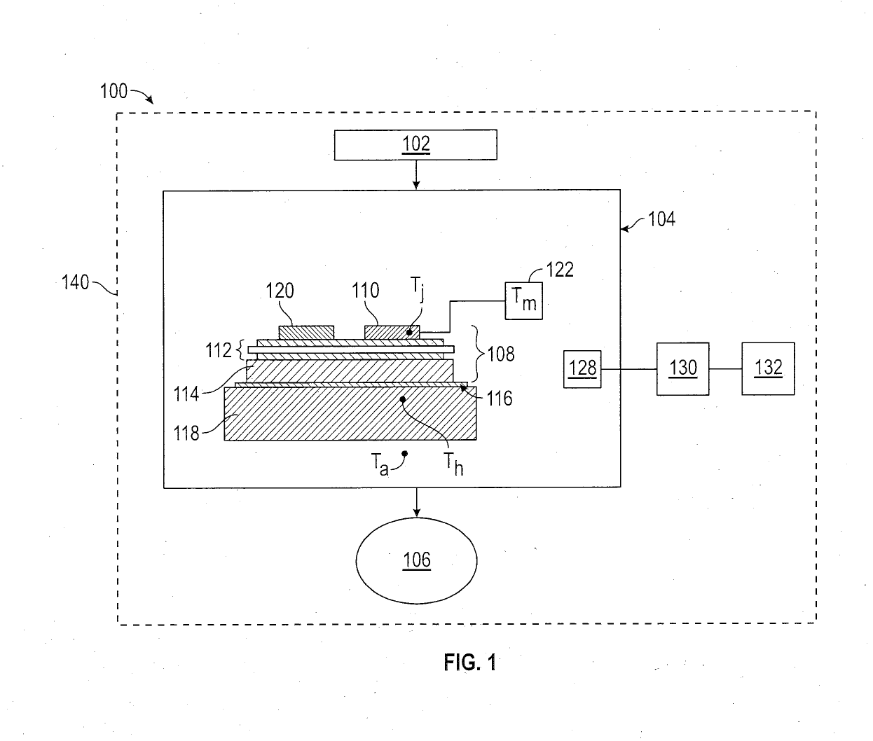

In accordance with an exemplary embodiment, FIG. 1 shows a schematic diagram 100 of an electrical system of a vehicle, such as an electrical vehicle 140. The diagram 100 includes a battery 102 that supplies direct current (DC) electricity to a power inverter module 104. The power inverter module 104 then provides alternating current (AC) electricity to an electric motor 106 of the vehicle. In one embodiment, the power inverter module 104 provides three-phase electrical power for the electric motor 106.

The power inverter module 104 includes an insulated gate bipolar transistor (IGBT) module 108 that is used to converter direct current (DC) power to alternating current (AC) power for the electrical components of the vehicle. The IGBT module 108 includes an IGBT junction 110, substrate 112 and base plate 114. The IGBT junction 110 is mounted on the substrate 112 and the substrate 112 is mounted on the base plate 114. The IGBT module 108 is coupled to a heat sink 118 by having the base plate 114 of the IGBT module 108 mounted and thermally coupled to the heat sink 118, with a layer of thermal grease 116 placed between the base plate 114 and the heat sink 118. Heat from the IGBT junction 110 is therefore conducted away from the IGBT junction 110 through the substrate 112, base plate 114, thermal grease 116 and heat sink 118. A freewheeling diode 120 is also attached to the substrate 112. When the IGBT module 108 is turned off, the freewheeling diode 120 is used to conduct current in a reverse direction. Also, a thermistor 122 coupled to the IGBT junction 110 measures a temperature of the IGBT junction 110.

Typical degradation mechanisms that lead to failure of the IGBT module 108 include gradual fatigue of solder joints and bond wires in the form of fracture, cracking, and wire lift-off, as well as thermal grease displacement. As the IGBT module 108 degrades, a thermal resistance between the IGBT junction 110 and the baseplate 114 increases, which results in heat build-up in the IGBT module 108 and/or IGBT junction 110. Also, gradual displacement of the thermal grease 116 causes heat to be non-uniformly distributed over a surface of the heat sink 118, thereby disrupting the heat transfer between the baseplate 114 and the heat sink 118.

In one embodiment, a model of the IGBT module 108 is used to estimate a thermal property of the IGBT module 108. A failure of the IGBT module 108 can be predicted by comparing a measured thermal property of the IGBT module 108 to an estimated value of the thermal property obtained from the model. When a difference between the measured thermal property and the estimated thermal property exceeds a selected threshold, a warning signal, alert signal or other indication can be sent for replacement or maintenance of the IGBT module 108

Various sensors are used to measure electrical and temperature parameters from various locations of the IGBT module, including heat sink temperatures Tₕ, ambient temperature Tₐ, junction temperature Tⱼ, etc., as well as stator voltages, current voltages, IGBT power, diode power, etc. These parameters are used within a model of the IGBT module 108 in order to estimate or predict thermal parameters of the IGBT module 108 that can be used for fault diagnosis and/or to determine remaining useful life (RUL) of the IGBT module 108.

Processor 130 receives the parameters from the sensors 128 and operates the model discussed herein in order to diagnose faults or determine RUL. A warning signal or alert signal can be sent from the processor 130 to a warning device 132 when a fault is diagnosed or when the RUL falls below a selected threshold. The warning device 132 can be a display, a light, and LED, and audio signal, a digital signal sent to the cloud, service personnel, design engineers, etc.

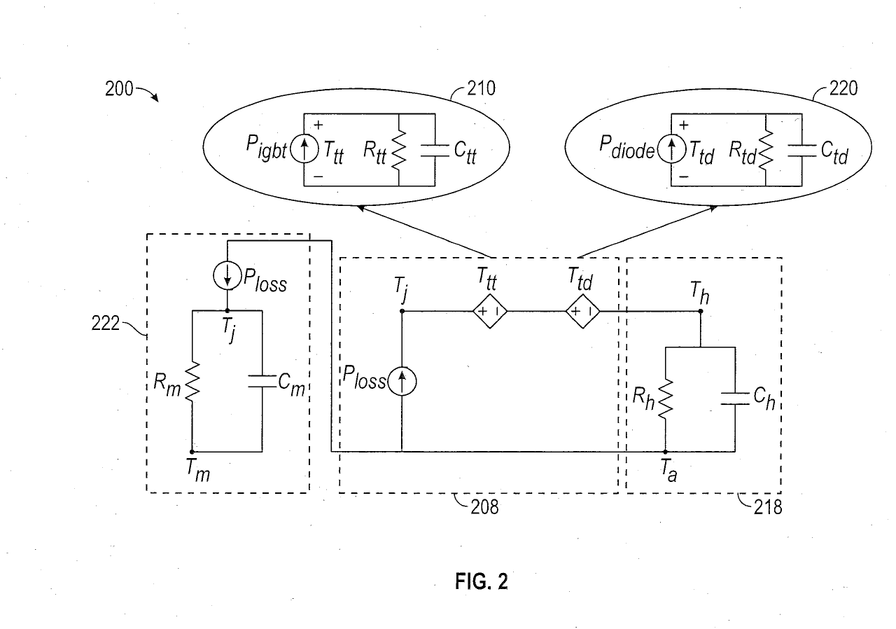

FIG. 2 shows an illustrative thermal model 200 of the IGBT module 108 that models a thermal response of various elements of the IGBT module 108. The thermal model 200 is in the form of a circuit diagram that includes various RC circuits that describe thermal flow through the elements of the IGBT module 108. Each RC circuit corresponds to an element of the IGBT module 108, such as the IGBT module 108, the heat sink 116, the thermistor 122, etc., and represents a thermal response of the element. In particular, a thermal response time constant for the n^{th} element is given by τₙ and is equal to the product of the thermal resistance and the thermal capacitance (i.e., τₙ=RₙCₙ).

Circuit 208 corresponds to the IGBT module 108 and describes thermal flow through the IGBT module 108. The circuit 208 includes a IGBT temperature term Tₜₜ that represents temperature of the IGBT junction 110 resulting from power loss across it, and a diode temperature term T_{td} that represents the temperature of the diode 120 resulting from power loss across it. The IGBT temperature term Tₜₜ is shown in detail in circuit 210. The diode temperature term T_{td} is shown in detail in circuit 220.

Circuit 210 represents heat flow between the IGBT junction 110 and the heat sink 118. The circuit 210 includes a power input term P_{igbt} that represents the power input into the IGBT module 108 at the IGBT junction 110. The IGBT junction 110 is represented by resistance Rₜₜ and capacitance Cₜₜ. The thermal response time constant for circuit 210 is given by τₜₜ=RₜₜCₜₜ. Similarly, circuit 220 represents heat flow between the diode 120 and the IGBT junction 110 and includes a power input term P_{diode} that represents the power input into the IGBT module 108 at the diode 120. The diode 120 is represented by resistance R_{td} and capacitance C_{td}. The thermal response time constant for the diode circuit 220 is given by τ_{td}=R_{td}C_{td}.

A heat sink circuit 218 represents a heat loss at the heat sink 118. The heat sink circuit 218 includes a node labelled Tₕ that represents the temperature of the heat sink 118 and a node labelled Tₐ that represents an ambient temperature or the region surrounding the IGBT module 108. Internal heat dissipation at the heat sink 118 is represented by resistance Rₕ and capacitance Cₕ. The thermal response time constant for the heat sink circuit 218 is given by τₕ=RₕCₕ. Circuit 222 represents a heat loss at a thermistor 122. The circuit 222 includes a node labelled Tⱼ that represents the temperature of the IGBT junction 110 and a node labelled Tₘ that represents the temperature of the thermistor 122. Internal heat dissipation at the thermistor 122 is represent by resistance Rₕ and capacitance Cₘ. The thermal response time constant for the thermistor circuit 222 is given by τₕ=RₕCₕ.

The dynamics of the thermal model in FIG. 2 is expressed in terms of the following differential equations expressed in the state space form:

\dot{x}=Ax+Bu Eq. (1)

\dot{y}=Cx Eq. (2)

where x is given by:

$$x = [ \begin{matrix}{T}_{j} - {T}_{td} - {T}_{h} \\ {T}_{td} \\ {T}_{h} - {T}_{a} \\ {T}_{j} - {T}_{m}\end{matrix} ] \qquad Eq . ( 3 )$$

and y=Tₘ−Tₐ defines the output of the state space model and comprises the difference between thermistor temperature Tₘ and ambient temperature Tₐ. A, B and C are matrices that are shown in detail in Eqs. (4)-(6).

$$\begin{matrix}A = [ \begin{matrix}- \frac{1}{{τ}_{tt}} & 0 & 0 & 0 \\ 0 & - \frac{1}{{τ}_{td}} & 0 & 0 \\ 0 & 0 & - \frac{1}{{τ}_{h}} & 0 \\ 0 & 0 & 0 & - \frac{1}{{τ}_{m}}\end{matrix} ] & Eq . ( 4 ) \\ B = [ \begin{matrix}\frac{1}{{C}_{tt}} & 0 \\ 0 & \frac{1}{{C}_{td}} \\ \frac{1}{{C}_{h}} & \frac{1}{{C}_{h}} \\ \frac{1}{{C}_{m}} & \frac{1}{{C}_{m}}\end{matrix} ] & Eq . ( 5 ) \\ C = [ 1 \; 1 \; 1 - 1 ] & Eq . ( 6 )\end{matrix}$$

The input to the model of Eq. (1) is the vector:

$$u = [ \begin{matrix}{P}_{igbt} \\ {P}_{diode}\end{matrix} ] \qquad Eq . ( 7 )$$

where P_{igbt} is power loss across the IGBT junction 110 and P_{diode} is a power loss across the diode 120.

In linear parametric form, the state space model can be rewritten as

z(t)=θ^{T}φ(t) Eq. (8)

where θ=[a₃, a₂, a₁, a₀, b₃, b₂, b₁, b₀]^{T} is a vector of parameters obtained from the transfer function denoted by T(s) of the model in Eq. (1)-(2) and given by:

$$T ( s ) = {C ( sI - A )}^{- 1} B = \frac{{b}_{3} {s}^{3} + {b}_{2} {s}^{2} + {b}_{1} s + {b}_{0}}{{s}^{4} + {a}_{3} {s}^{3} + {a}_{2} {s}^{2} + {a}_{1} s + {a}_{0}} ,$$

where I is a 4×4 identity matrix. The Laplace transforms of z(t) and φ(t) are given by:

$$\begin{matrix} Z ( s ) = \frac{{s}^{4}}{Λ ( s )} Y ( s ) & Eq . ( 9 ) \\ Φ ( s ) = {( \begin{matrix}- \frac{{s}^{3}}{Λ ( s )} Y ( s ) , … , - \frac{1}{Λ ( s )} Y ( s ) , \frac{{s}^{3}}{Λ ( s )} {U}_{igbt} ( s ) , … , \frac{1}{Λ ( s )} {U}_{igbt} ( s ) , … , \\ \frac{{s}^{3}}{Λ ( s )} {U}_{diode} ( s ) , … , \frac{1}{Λ ( s )} {U}_{diode} ( s )\end{matrix} )}^{T} & Eq . ( 10 )\end{matrix}$$

respectively, where Y(s) is the Laplace transform of y(t), U_{igbt}(s) and U_{diode}(s) are the Laplace transforms of P_{igbt} and P_{diode}, respectively, and Λ(s) is a 4^{th} order low-pass filter. Calculating Eq. (8) yields a new output z(t) and a new input φ(t).

A recursive least-squares process (RLSE) is used to estimate the thermal parameters of the model, i.e., entries of A and B. Eqs. (11) and (12) provide the parameters of the RLSE:

\dot{\hat{θ}}=−Peₙφ Eq. (11)

\dot{P}=βP−Pφφ^{T}P/m Eq. (12)

where \hat{θ} denotes an estimate of θ, P is a covariance matrix, β>0 is a design parameter selected to ensure exponential convergence, and eₙ is a normalized estimate error given by Eqs. (13) and (14):

$$\begin{matrix}{e}_{n} = \frac{\hat{z} - z}{m} & Eq . ( 13 ) \\ m = 1 + {ϕ}^{T} P ϕ & Eq . ( 14 )\end{matrix}$$

Running the RLSE provides an estimate \hat{θ} of the state parameter. The estimate \hat{θ} converges to the actual values θ as the RLSE is performed through several iterations.

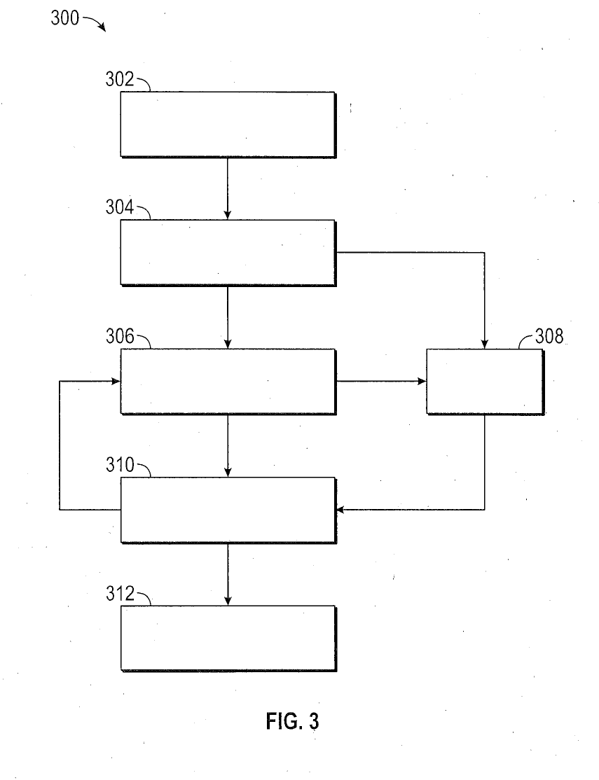

FIG. 3 shows a flowchart 300 illustrating a method for running the model for the IGBT module 108 shown in FIG. 2. In box 302, input signals to the model are entered. Exemplary input signals include P_{igbt} and P_{diode}, which are shown at circuits 210 and 220 of FIG. 2. In box 304, an actual IGBT module 108 is run at the input signals indicated in box 302 in order to obtain actual thermal property measurements which are provided as state space parameters (z). In box 306, the input signals are provided to the model (FIG. 2) in order to obtain an estimate of the state space parameters (\hat{z}). The state space parameters z and the estimated state space parameters \hat{z} are provided to box 308. At box 308, error parameters are determined between the state space parameters and the estimate state space parameters. The error parameters (i.e., eₙ and m) are provided to box 310. At box 310, the model parameters (i.e., the parameters of matrices A and B) are determined using RLSE. The method then returns to box 306, where the newly updated values of matrices A and B are used to obtain new estimates of the state space parameters, \hat{z}. Boxes 306, 308 and 310 form a recursive loop that allows the model parameters to converge to the actual parameters of the IGBT module 108 with each iteration. At box 312, the parameters determined in box 310 are used to track parameters of the IGBT module 108 in order to assess the health or determine the condition of the IGBT module 108.

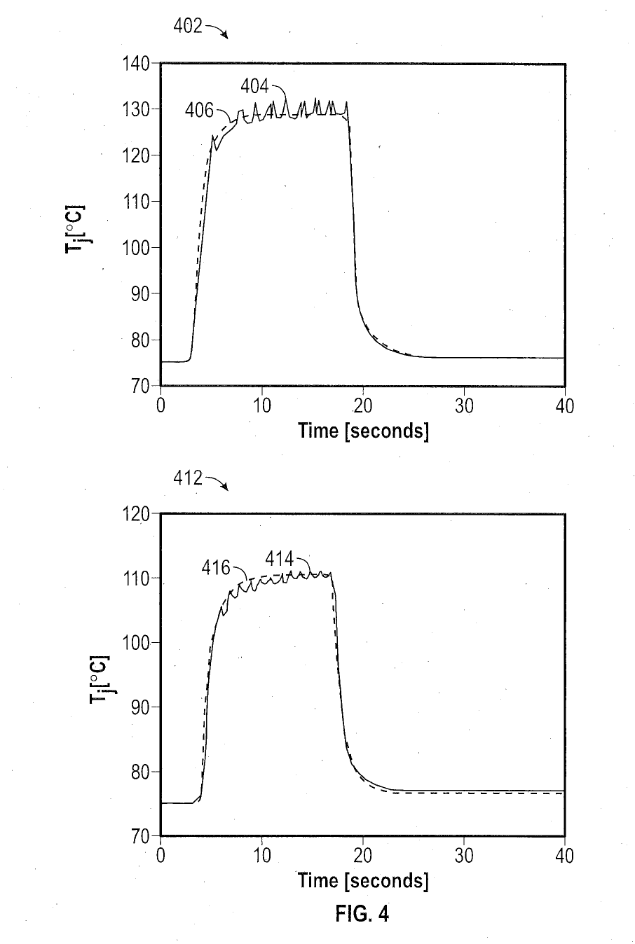

FIG. 4 shows two graphs 402 and 412 with illustrative heating curves for the IGBT junction 110. Graph 402 shows a temperature measurement 404 from the IGBT junction 110 after running the motor at a speed of 1000 revolutions per minute (rpm) and producing a torque of 360 Newton-meters (Nm). Also shown in graph 402 is a predicted temperature 406 obtained using the model of FIG. 2 operated with speed of 1000 rpm and torque of 360 Nm. The predicted temperature 406 shows good agreement with temperature measurement 404. Similarly, graph 412 shows a temperature measurement 414 from the IGBT junction 110 after running the motor at a speed of 3000 rpm and producing a torque of 270 Nm. Also shown in graph 412 is predicted temperature 416 obtained using the model of FIG. 2 operated at a speed of 3000 rpm and a torque of 270 Nm. The predicted temperature 416 shows good agreement with the temperature measurement 414.

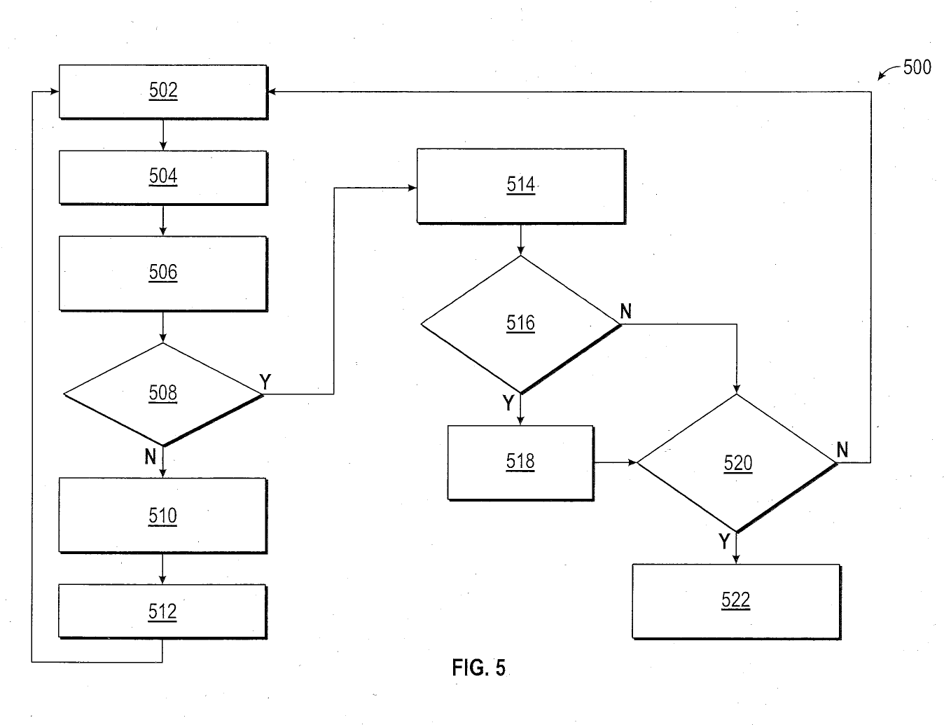

FIG. 5 shows a flowchart 500 illustrating a method of determining a faulty condition of the IGBT module 108 using the model of FIG. 2. In Box 502, various electrical parameters for operating the IGBT module 108 are obtained or measured, such as stator voltages, stator currents, DC link voltage, etc. In box 504, IGBT and diode power loses are computed (i.e., P_{igbt} and P_{diode}). In box 506, the thermistor is used to obtain thermistor temperature measurements.

In box 508, the processor determines whether the IGBT module system has been initialized. If, at box 508, the model has not been initialized, the method proceeds to box 510. At box 510, a recursive least squares estimation (RLSE) is run to obtain nominal thermal model parameters. Then in box 512, threshold values are computed from the thermal parameters. Once the thermal parameters have been computed, the method returns to box 502.

Returning to box 508, if the model has been initialized, the method proceeds to box 514. At box 514, the RLSE is run on the model to obtain thermal model parameters. At box 516, a decision is made as to whether the IGBT thermal resistance (Rₜₜ) is greater than a determined Rₜₜ threshold. If the IGBT thermal resistance Rₜₜ is not greater than the Rₜₜ threshold, then the method proceeds to decision box 520. If the IGBT thermal resistance Rₜₜ is greater than the Rₜₜ threshold, the method proceeds to box 518, at which point a warning indicating degradation of the IGBT junction is issued. The method then proceeds from box 518 to box 520.

At box 520, a decision is made as to whether the heat sink thermal resistance Rₘ is greater than an Rₘ threshold. If the heat sink thermal resistance Rₘ is greater than the threshold, then a warning or alert is issued at box 522 to indicate a degradation in the efficiency of heat sink cooling. If the heat sink thermal resistance Rₘ is less than the Rₘ threshold, the method returns from box 520 to box 502. The process thus continuously iterates based on updated conditions of the IGBT module 108.

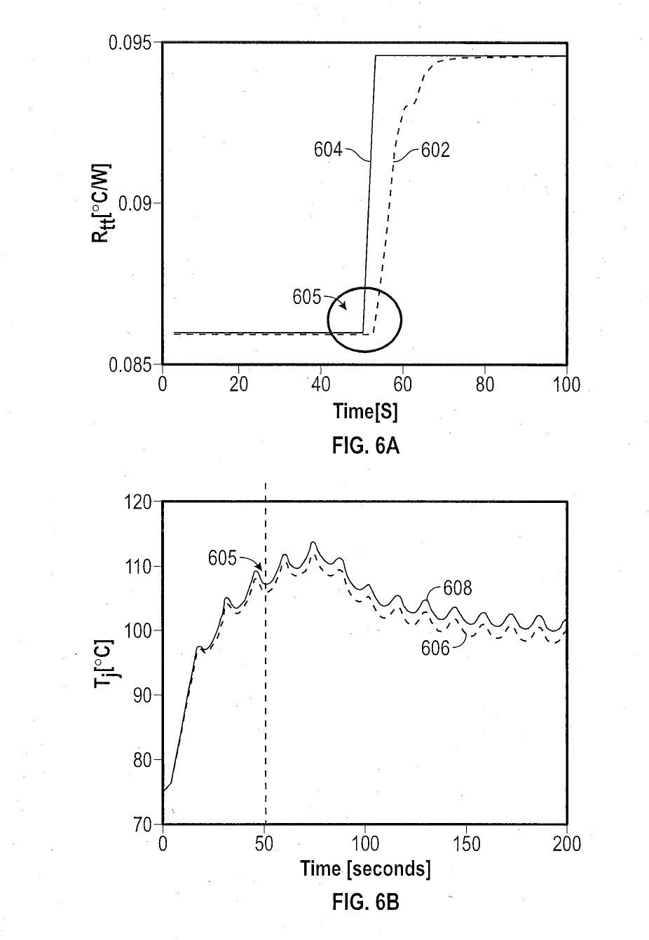

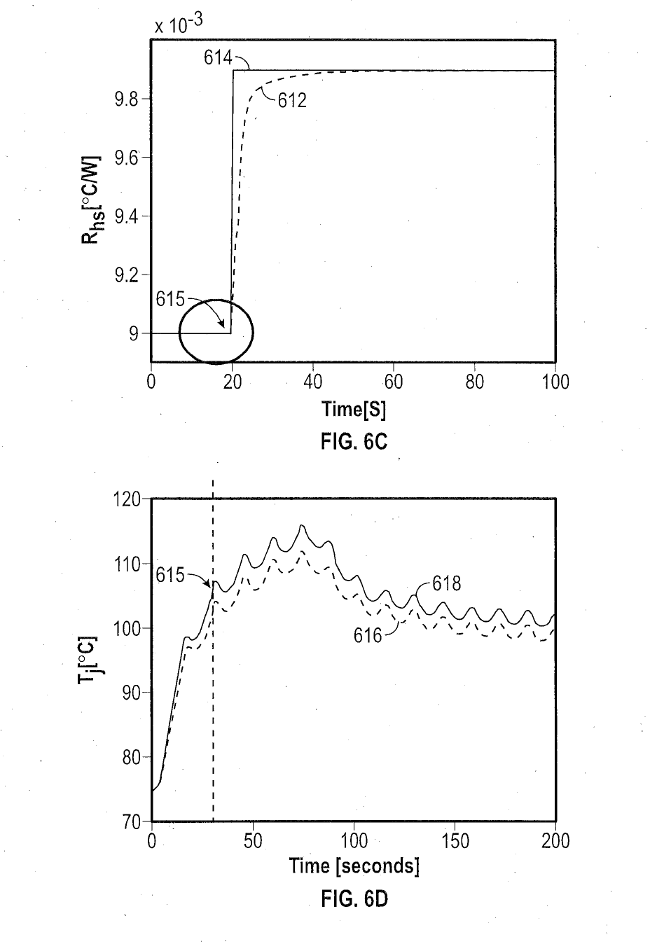

FIG. 6A shows a plot of thermal resistance between the IGBT junction and the heat sink (Rₜₜ). The plot shows thermal resistance Rₜₜ along the ordinate axis and time in seconds along the abscissa. Curve 602 represents an estimated value of Rₜₜ during normal operation of the IGBT module 108. Curve 604 represents an actual thermal resistance during a faulty condition of the IGBT module 108. At a time of about 50 seconds (indicated by arrow 605), a fault occurs that causes the actual thermal resistance to deviate from the estimated thermal resistance Rₜₜ by an amount that exceeds a threshold, thereby causing a warning signal or alert signal to be generated. For the thermal resistance Rₜₜ, the threshold has been set at a 10% increase of the actual Rₜₜ vs. the estimate Rₜₜ.

FIG. 6B shows a plot of junction temperature Tⱼ vs. time that is related to the plot of thermal resistance shown in FIG. 6A. Curve 606 represents a junction temperature during normal operations and curve 608 represents junction temperature during faulty operations (i.e., affected by the fault occurring at 50 seconds in FIG. 6A). Curves 606 and 608 are well matched for the first 50 seconds of operation. After about 50 seconds, the curve 606 representing normal operation deviates from the curve 608 representing faulty operations.

FIG. 6C shows a plot of thermal resistance for the heat sink (Rₕ). The plot shows thermal resistance Rh along the ordinate axis and time in seconds along the abscissa. Curve 612 represents an estimated value of Rₕ during normal operation of the IGBT module 108. Curve 614 represents an actual thermal resistance of the heat sink during a faulty operation of the IGBT module 108. At a time of about 20 seconds (arrow 615), a fault occurs that causes the actual thermal resistance Rₕ of the heat sink to deviate from the estimated thermal resistance Rₕ of the heat sink by an amount that exceeds a threshold set at about 10%, thereby causing a warning signal or alert signal to be generated.

FIG. 6D shows a plot of junction temperature Tⱼ vs. time that is related to the plot of thermal resistance Rₕ for the heat sink as shown in FIG. 6C. Curve 616 represents a junction temperature of the heat sink during normal operations and curve 618 represents junction temperature of the heat sink during faulty operations (i.e., affected by the fault occurring at 20 seconds (arrow 615) in FIG. 6C). Curves 606 and 608 are well matched for the first 20 seconds of operation. After about 20 seconds however, the curve 606 represent normal operations deviates from the curve 608 representing faulty operations.

The model disclosed herein can also be used to determine a remaining useful life (RUL) of the IGBT module 108. The health of the IGBT junction 110 is affected by high temperature levels and temperature oscillations inside the IGBT junction 110, which are typically caused either by electrical power dissipated in the IGBT junction 110 (also referred to as power cycling) or by ambient temperature variations (also referred to as passive thermal cycling). The RUL of an IGBT junction depends on a number of power cycles the IGBT junction is able to withstand.

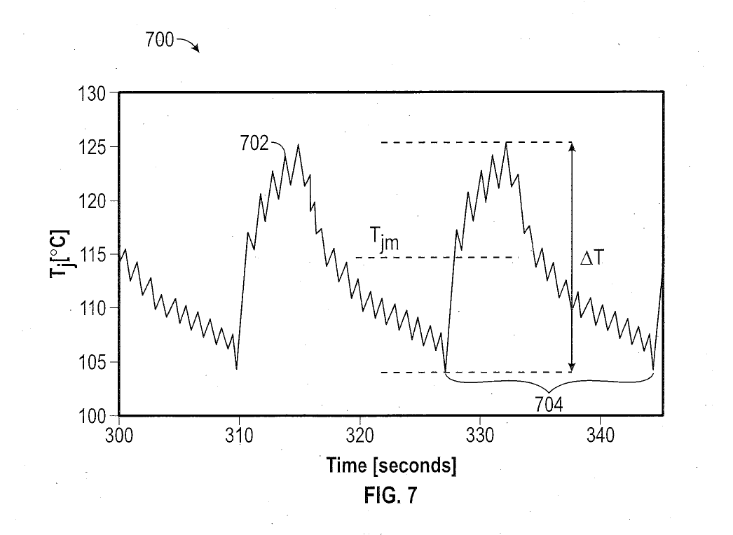

FIG. 7 shows a graph 700 illustrating active power cycling. Each power cycle occurs because of the electrical load variation. A selected power cycle produces a periodic waveform 702 that is characterized by a peak-to-peak temperature difference, or temperature swing, ΔTⱼₘ and an average junction temperature Tⱼₘ. A k^{th} power cycle 704 shown in FIG. 7 and is characterized by average junction temperature Tⱼₘ(k) and a temperature swing ΔT(k). The number of power cycles remaining before failure for a steady state power cycle obeys a Coffin-Manson law:

$$N = A \cdot Δ {T}^{α} \cdot exp \{ \frac{{E}_{a}}{{k}_{B} \cdot {T}_{jm}} \} \qquad Eq . ( 15 )$$

where Boltzmann constant k_{B}=1.380×10⁻²³ J/K, activation energy Eₐ=9.89×10⁻²⁰ J, and the parameters A=302500 K^{-α} and α=−5.039.

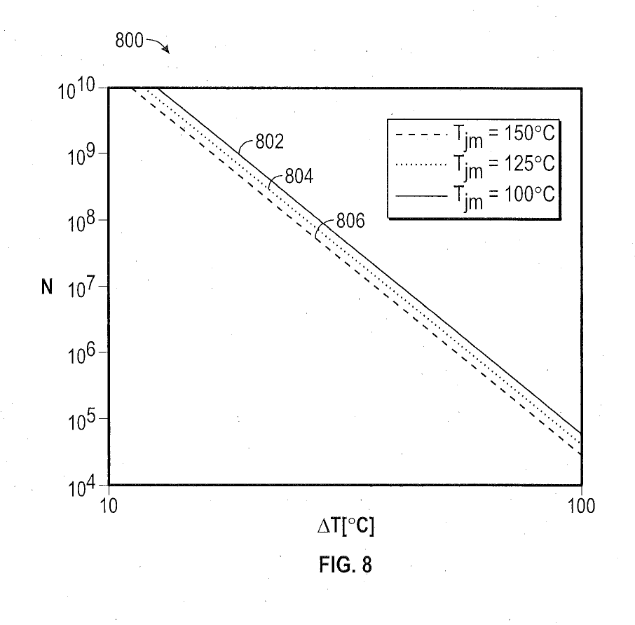

FIG. 8 shows a graph 800 illustrating a set of power cycling capability curves. Log(ΔT) is shown along the abscissa and log(N) is shown along the ordinate axis. Capability curves 802, 804 and 806 represent average temperatures Tⱼₘ of 100° C., 125° C. and 150° C., respectively. Each capability curve provides roughly a straight line when plotted as log(N) vs. log(ΔT). As can be observed from Eq. (15) or from observation of FIG. 8, large temperature swings (e.g., ΔT>40° C.) at high temperature levels (e.g., Tⱼₘ>100° C.) can shorten the remaining number of cycles of an IGBT junction quicker than smaller swings (e.g., ΔT<20° C.) at low temperature levels.

When determining a remaining useful life, a Kalman filter or other suitable estimation technique can be used to estimate junction temperature Tⱼ. The Kalman filter can be applied to the Eqs. (1)-(3) wherein the entries to matrices A and B are determined in Eqs. (4)-(5). RLSE is used prior to the Kalman filter in order to estimate the thermal model parameters of A and B. These estimated parameters can then be used to estimate IGBT junction temperature Tⱼ using the Kalman filter.

Once A and B are determined, the Kalman filter is applied to the model of Eqs. (1)-(3) to estimate the junction temperature. The Kalman filter includes a time update given by Eqs. (16) and (17):

\hat{x}_{k̅}=A\hat{x}ₖ₋₁+Buₖ₋₁ Eq. (16)

P_{k̅}=APₖ₋₁A^{T}+Q Eq. (17)

and a measurement update, given by Eqs. (18)-(20):

Kₖ=P_{k̅}C^{T}(CP_{k̅}C^{T}+R)⁻¹ Eq. (18)

\hat{x}ₖ=\hat{x}_{k̅}+Kₖ(yₖ−C\hat{x}_{k̅}) Eq. (19)

Pₖ=(I−KₖC)P_{k̅} Eq. (20)

where \hat{x}ₖ is the estimate of x at time step k, Kₖ is the Kalman gain at time step k, and Pₖ is the covariance matrix at time step k. Q and R are process and measurement noise covariance matrices, which are selected to be constant.

Estimating the RUL of an IGBT junction can be performed based on estimate of the average junction temperature \hat{T}ⱼₘ. Once the state variable \hat{x} is obtained for the k^{th} power cycle, it is possible to compute an estimate of temperature swing Δ\hat{T}(k), and the average junction temperature estimates \hat{T}ⱼₘ (k) for the power cycle.

Temperature swing and mean temperature per cycle are highly varying parameters due to normal fluctuations in electrical loads. Eq. (21) computes an effective number of power cycles to failure when there is fluctuation in temperature swings and in average temperatures:

$$log {N}_{e} ( n ) = \frac{1}{n} {\sum }_{k = 1}^{n} log N ( Δ \hat{T} ( k ) , {\hat{T}}_{jm} ( k ) ) \qquad Eq . ( 21 )$$

where log Nₑ(n) denotes an average of log N (Δ\hat{T}(k), \hat{T}ⱼₘ(k)) evaluated at estimated temperature swings Δ\hat{T}(k) and mean temperature \hat{T}ⱼₘ (k) for each power cycle k, and n is the number of power cycles that have occurred. Thus, the number of remaining power cycles before IGBT module fails is equal to Nₑ(n)−n, which can be converted into actual remaining time to failure (RUL) an expected or predicted load, which can be related to a driving pattern of a vehicle driver.

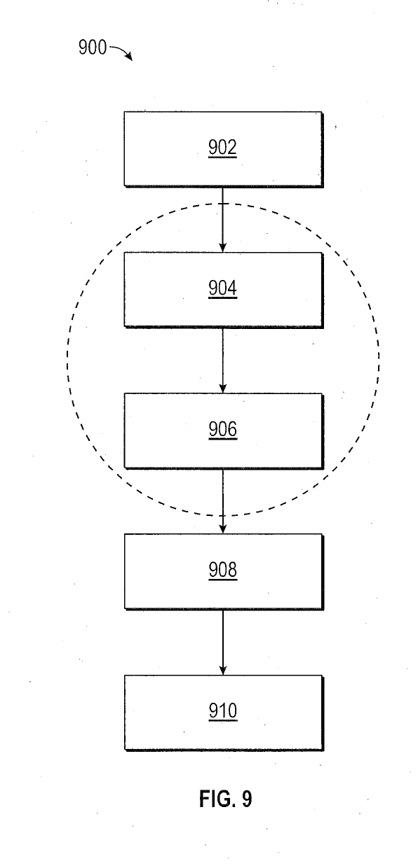

FIG. 9 shows a flowchart 900 illustrating a method of determining remaining useful life of the IGBT module. In box 902, the inputs signals are presented to the model. The inputs signals can be the P_{igbt} and P_{diode} power losses, etc. In box 904, the model is run, including the Eqs. (1)-(7). In box 906, an RLSE is operated on the model to obtain the parameters of the matrices A and B, using Eqs. (8)-(14). In box 908, the Kalman filter (Eqs. (16)-(20)) or other estimation technique is applied in order to determine average temperatures and temperature swings in the power cycles. In box 910, the RUL is predicted for an average temperature and temperature swing determined from the Kalman filter and the Eq. (21).

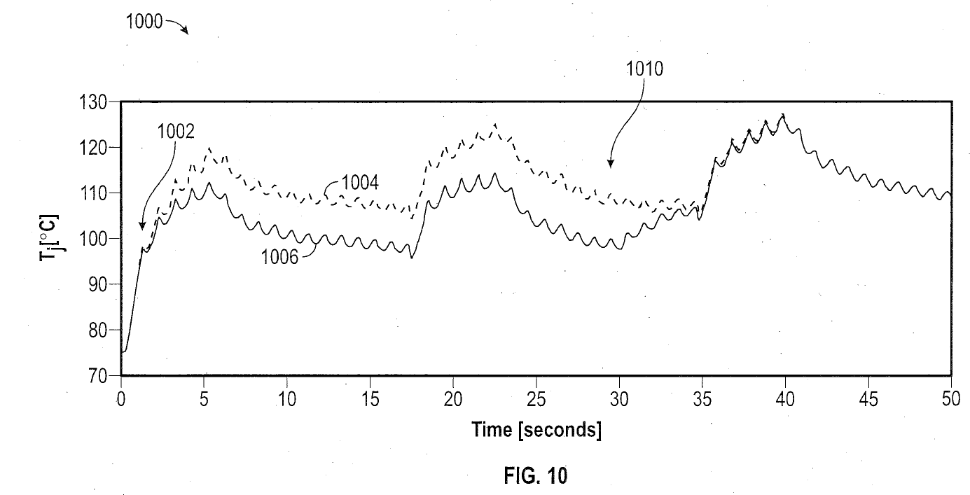

FIG. 10 shows simulation results 1000 demonstrating how the method disclosed herein predicts the RUL of an IGBT module. The simulation shows an IGBT junction temperature over time during operation of the IGBT junction. A fault occurs at the time indicated by arrow 1002. The fault is a solder fatigue at the interface of the IGBT substrate and the base plate. Application of the RLSE has the estimated temperature 1004 diverging from the actual temperature 1006. The Kalman filter is applied at the time indicated by arrow 1010.

Applying the Kalman filter causes the estimate of the junction temperature \hat{T}ⱼ to converge to the actual Tⱼ, as shown in FIG. 10. The estimate \hat{T}ⱼ is used to compute junction temperature swing and mean junction temperature and to count the number of power cycles that have occurred, thus allowing a calculation of the number of remaining power cycles.

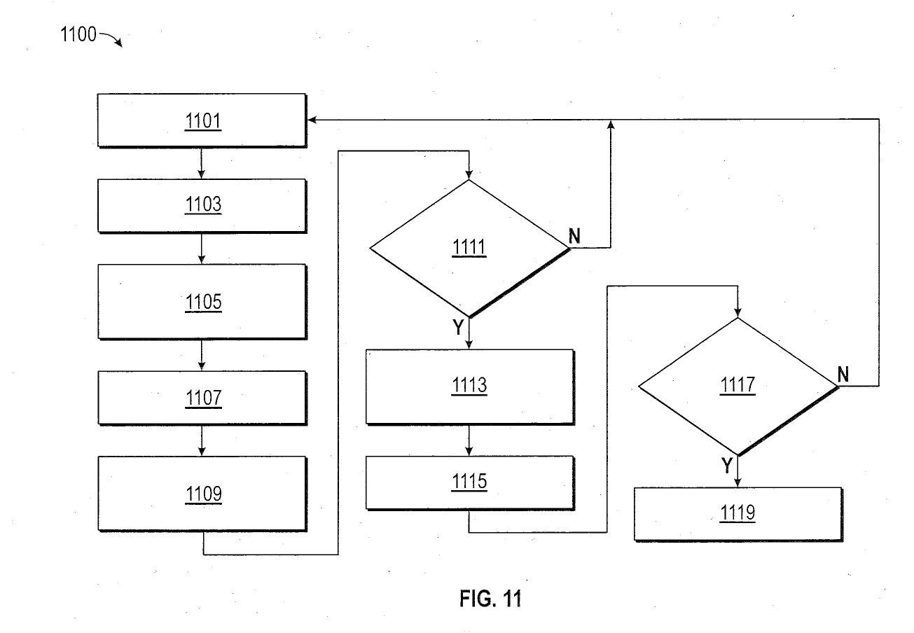

FIG. 11 shows a flowchart 1100 illustrating a method of providing a warning or alert based on a remaining useful life of an IGBT junction. In box 1101, electrical parameters of the IGBT junction are collected or measured. These electrical parameters include, but are not limited to, stator voltages, stator currents DC link voltage, etc. In box 1103, IGBT junction power losses and diode power losses are computed. In box 1105, thermistor temperature measurements are obtained. In box 1107, a recursive least squares estimator (RLSE) is performed on a model of the IGBT module to determine matrices A and B. In box 1109, a Kalman filter is run in order to estimate the IGBT junction temperature and temperature swings.

In box 1111, a decision is made as to whether the junction temperature swing is greater than a selected temperature threshold. If the temperature swing is less than or equal to the temperature threshold, then the method returns to box 1101. However, if the temperature swing is greater than the temperature threshold, then the method proceeds to box 1113. In box 1113, the number of completed power cycles is incremented by one. In box 1115, the remaining number of power cycles (i.e., Nₑ) is calculated, for example, using Eq. (21). In box 1117, a decision is made as to whether the remaining number of power cycles is less than a count threshold. If the remaining number of power cycles is greater than or equal to the count threshold, the method returns to box 1101. However, if the remaining number of power cycles is less than the count threshold, then the method proceeds to box 1119. At box 1119, an IGBT degradation warning or alert is issued.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof

What is claimed is:

1. A method of determining occurrence of a fault at an insulated-gate bipolar transistor (IGBT) module, comprising:
operating a model of the IGBT module on a processor to estimate a thermal parameter of the IGBT module under normal operation conditions;
measuring a thermal parameter of the IGBT module via a sensor; and
providing an alert signal to indicate the occurrence of the fault when a difference between the estimated thermal parameter and the measured thermal parameter is greater than a selected threshold.

2. The method of claim 1, wherein the thermal parameter is at least one of: (i) a thermal resistance between the IGBT junction and a heat sink; (ii) a thermal resistance between a diode and the IGBT junction; (iii) a thermal resistance of a heat sink; and (iv) a thermal resistance of a thermistor.

3. The method of claim 1, wherein the thermal parameter is one of: (i) a thermal capacitance; (ii) a thermal resistance; and (iii) a thermal time constant of an element of the IGBT module.

4. The method of claim 1, further comprising determining the selected threshold from the estimated thermal parameters obtained from the model of the IGBT module.

5. The method of claim 1, further comprising determining a remaining useful life of the IGBT module.

6. The method of claim 5, wherein determining the remaining useful life further comprises obtaining an effective number of power cycles related to a summation of power cycles at a plurality of average temperatures and temperature swings.

7. The method of claim 6, further comprising applying an estimation technique to the model of the IGBT module to estimate the average temperature and temperature swing of the power cycles.

8. An apparatus for assessing a condition of an insulated-gate bipolar transistor (IGBT) module, comprising:
a sensor configured to obtain a measurement of a thermal parameter of the IGBT module; and
a processor configured to:
receive the measured thermal parameter from the sensor,
run a model of the IGBT module to determine a thermal parameter of the IGBT module under normal operation conditions, and
provide an alert signal to indicate the occurrence of the fault when a difference between the estimated thermal parameter and the measured thermal parameter is greater than or equal to a selected threshold.

9. The apparatus of claim 8, wherein the thermal parameter is at least one of: (i) a thermal resistance between the IGBT junction and a heat sink; (ii) a thermal resistance between a diode and the IGBT junction; (iii) a thermal resistance of a heat sink; and (iv) a thermal resistance of a thermistor.

10. The apparatus of claim 8, wherein the thermal parameter is one of: (i) a thermal capacitance; (ii) a thermal resistance; and (iii) a thermal time constant of an element of the IGBT module.

11. The apparatus of claim 8, wherein the processor is further configured to determine the selected threshold from the estimated thermal parameters obtained by running the model of the IGBT module.

12. The apparatus of claim 8, wherein the processor is further configured to determine a remaining useful life of the IGBT junction.

13. The apparatus of claim 12, wherein the remaining useful life further comprises an effective number of power cycles related to a summation of power cycles at a plurality of average temperatures and temperature swings.

14. The apparatus of claim 13, wherein the processor is further configured to apply an estimation technique to the model of the IGBT module to estimate the average temperature and temperature swing of the power cycles.

15. A vehicle, comprising:
an IGBT module;
a sensor configured to obtain a measurement of a thermal parameter of the IGBT module; and
a processor configured to:
receive the measured thermal parameter from the sensor,
run a model of the IGBT module to determine a thermal parameter of the IGBT module under normal operation conditions, and
provide an alert signal to indicate the occurrence of the fault when a difference between the estimated thermal parameter and the measured thermal parameter is greater than or equal to a selected threshold.

16. The vehicle of claim 15, wherein the thermal parameter is at least one of: (i) a thermal resistance between the IGBT junction and a heat sink; (ii) a thermal resistance between a diode and the IGBT junction; (iii) a thermal resistance of a heat sink; and (iv) a thermal resistance of a thermistor.

17. The vehicle of claim 15, wherein the thermal parameter is one of: (i) a thermal capacitance; (ii) a thermal resistance; and (iii) a thermal time constant of an element of the IGBT module.

18. The vehicle of claim 15, wherein the processor is further configured to determine the selected threshold from the estimated thermal parameters obtained by running the model of the IGBT module.

19. The vehicle of claim 15, wherein the processor is further configured to determine a remaining useful life of the IGBT junction from an effective number of power cycles related to a summation of power cycles at a plurality of average temperatures and temperature swings.

20. The vehicle of claim 19, wherein the processor is further configured to apply an estimation technique to the model of the IGBT module to estimate the average temperature and temperature swing of the power cycles.
